(19) United States
(12) Patent Application Publication
(10) Pub. No.: US 2023/0028475 A1
(43) Pub. Date: Jan. 26, 2023

(54) PACKAGE IO ESCAPE ROUTING ON A DISAGGREGATED SHORELINE

(71) Applicants: Ankireddy Nalamalpu, Portland, OR (US); Mahesh K. Kumashikar, Bangalore (IN); Atul Maheshwari, Portland, OR (US); Lai Guan Tang, Tanjung Bungah (MY)

(72) Inventors: Ankireddy Nalamalpu, Portland, OR (US); Mahesh K. Kumashikar, Bangalore (IN); Atul Maheshwari, Portland, OR (US); Lai Guan Tang, Tanjung Bungah (MY)

(21) Appl. No.: 17/957,204

(22) Filed: Sep. 30, 2022

(51) Int. Cl. H01L 23/538; H01L 23/498; H03K 19/17736; H03K 19/1776; H01L 25/065

(52) U.S. Cl. CPC H01L 23/5381; H01L 23/5386; H01L 23/5384; H01L 23/49827; H01L 23/49838; H03K 19/17744; H03K 19/1776; H01L 25/0655

(57) ABSTRACT

A system includes a first die having a first side with first die-to-die circuitry and first input output circuitry. The system also includes a second die comprising a second side with second die-to-die circuitry and second input output circuitry. The first and second sides are adjacent to each other in the electronic package device. The system also includes a semiconductor interconnect including multiple connections to interconnect the first and second die-to-die circuitries. The semiconductor interconnect also includes multiple through-silicon-vias to transmit data to or from the first and second input output circuitries through the semiconductor bridge.

### BACKGROUND

The present disclosure relates generally to routing in a multi-die package. More particularly, the present disclosure relates to using escape routing through interconnects (e.g., bridge, interposer, etc.) to provide additional shoreline to the package.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Integrated circuits, such as field programmable gate arrays (FPGAs) are programmed to perform one or more particular functions. Multiple integrated circuit devices (e.g., chips or die) may be coupled together in a package that incorporate interconnections between the integrated circuit devices. However, these interconnections may limit the available shoreline(s) of the integrated circuit devices and the package that are available for use in enabling data to be transmitted from (e.g., escape) the package.

### BRIEF DESCRIPTION OF THE DRAWINGS

Various aspects of this disclosure may be better understood upon reading the following detailed description and upon reference to the drawings in which:

FIG. 1 is a block diagram of a system used to program an integrated circuit device, in accordance with an embodiment of the present disclosure;

FIG. 2 is a block diagram of the integrated circuit device of FIG. 1, in accordance with an embodiment of the present disclosure;

FIG. 3 is a diagram of programmable fabric of the integrated circuit device of FIG. 1, in accordance with an embodiment of the present disclosure;

FIG. 4 is a block diagram of a side view of a multi-die package having die-to-die circuitry occupying a shoreline of the die of the multi-die package, in accordance with an embodiment of the present disclosure;

FIG. 5 is a block diagram of top view of the multi-die package of FIG. 4, in accordance with an embodiment of the present disclosure;

FIG. 6 is a block diagram of a side view of a multi-die package having die-to-die circuitry and input output circuitry both along a shoreline of the die of the multi-die package, in accordance with an embodiment of the present disclosure;

FIG. 7 is a block diagram of a side view of a multi-die package having die-to-die circuitry and input output circuitry both along a shoreline of the die of the multi-die package, in accordance with an embodiment of the present disclosure;

FIG. 8 is a block diagram of a top view of the multi-die package of FIG. 6 or 7, in accordance with an embodiment of the present disclosure; and

FIG. 9 is a block diagram of a data processing system, in accordance with an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

Silicon packages may have multiple die in the package that utilize die-to-die circuitry to enable communication between the multiple die. However, this die-to-die circuitry may consume some or all of the available shoreline on edges/sides between the die. This shoreline may be key for communication off package using IO circuitry. Thus, to expand shoreline functionality, the interconnect may include through-silicon-vias to enable the IO circuitry to send and receive data off package even when the die-to-die circuitry consumes an outermost portion of a shoreline.

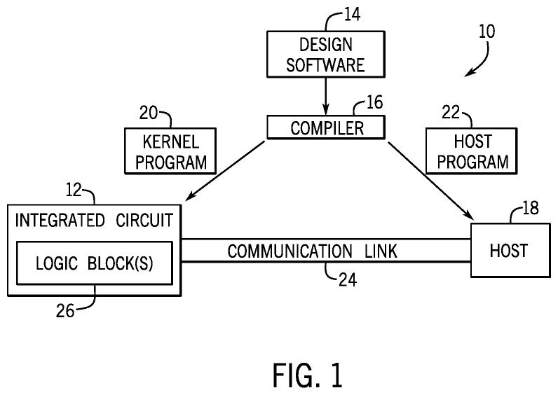

With the foregoing in mind, FIG. 1 illustrates a block diagram of a system 10 that may implement arithmetic operations. A designer may desire to implement functionality, such as the operations of this disclosure, on an integrated circuit device 12 (e.g., a programmable logic device, such as a field programmable gate array (FPGA) or an application specific integrated circuit (ASIC)). In some cases, the designer may specify a high-level program to be implemented, such as an OPENCL® program, which may enable the designer to more efficiently and easily provide programming instructions to configure a set of programmable logic cells for the integrated circuit device 12 without specific knowledge of low-level hardware description languages (e.g., Verilog or VHDL). For example, since OPENCL® is quite similar to other high-level programming languages, such as C++, designers of programmable logic familiar with such programming languages may have a reduced learning curve than designers that are required to learn unfamiliar low-level hardware description languages to implement new functionalities in the integrated circuit device 12.

The designer may implement high-level designs using design software 14, such as a version of INTEL® QUARTUS® by INTEL CORPORATION. The design software 14 may use a compiler 16 to convert the high-level program into a lower-level description. In some embodiments, the compiler 16 and the design software 14 may be packaged into a single software application. The compiler 16 may provide machine-readable instructions representative of the high-level program to a host 18 and the integrated circuit device 12. The host 18 may receive a host program 22 which may be implemented by the kernel programs 20. To implement the host program 22, the host 18 may communicate instructions from the host program 22 to the integrated circuit device 12 via a communications link 24, which may be, for example, direct memory access (DMA) communications or peripheral component interconnect express (PCIe) communications. In some embodiments, the kernel programs 20 and the host 18 may enable configuration of a logic block 26 on the integrated circuit device 12. The logic block 26 may include circuitry and/or other logic elements and may be configured to implement arithmetic operations, such as addition and multiplication.

The designer may use the design software 14 to generate and/or to specify a low-level program, such as the low-level hardware description languages described above. Further, in some embodiments, the system 10 may be implemented without a separate host program 22. Moreover, in some embodiments, the techniques described herein may be implemented in circuitry as a non-programmable circuit design. Thus, embodiments described herein are intended to be illustrative and not limiting.

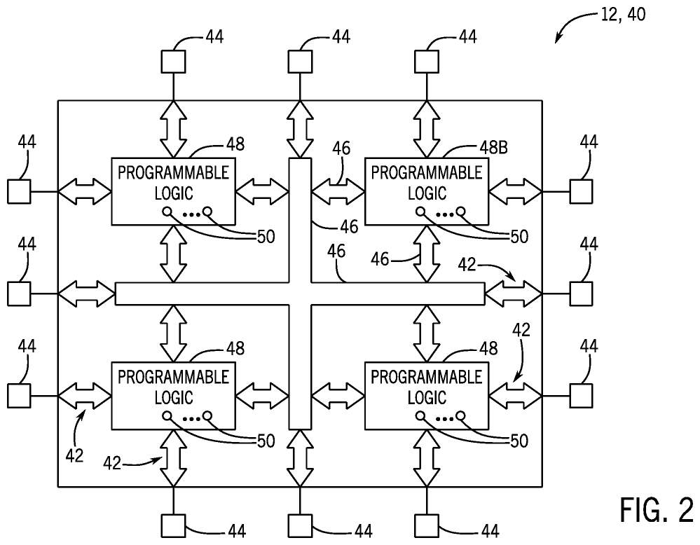

Turning now to a more detailed discussion of the integrated circuit device 12, FIG. 2 is a block diagram of an example of the integrated circuit device 12 as a programmable logic device, such as a field-programmable gate array (FPGA). Further, it should be understood that the integrated circuit device 12 may be any other suitable type of programmable logic device (e.g., an ASIC and/or application-specific standard product). The integrated circuit device 12 may have input/output (TO) circuitry 42 for driving signals off device and for receiving signals from other devices via input/output pins 44. Interconnection resources 46, such as global and local vertical and horizontal conductive lines and buses, and/or configuration resources (e.g., hardwired couplings, logical couplings not implemented by user logic), may be used to route signals on integrated circuit device 12. Additionally, interconnection resources 46 may include fixed interconnects (conductive lines) and programmable interconnects (i.e., programmable connections between respective fixed interconnects). Programmable logic 48 may include combinational and sequential logic circuitry. For example, programmable logic 48 may include look-up tables, registers, and multiplexers. In various embodiments, the programmable logic 48 may be configured to perform a custom logic function. The programmable interconnects associated with interconnection resources may be considered to be a part of programmable logic 48.

Programmable logic devices, such as the integrated circuit device 12, may include programmable elements 50 with the programmable logic 48. In some embodiments, at least some of the programmable elements 50 may be grouped into logic array blocks (LAB s). As discussed above, a designer (e.g., a customer) may (re)program (e.g., (re)configure) the programmable logic 48 to perform one or more desired functions. By way of example, some programmable logic devices may be programmed or reprogrammed by configuring programmable elements 50 using mask programming arrangements, which is performed during semiconductor manufacturing. Other programmable logic devices are configured after semiconductor fabrication operations have been completed, such as by using electrical programming or laser programming to program programmable elements 50. In general, programmable elements 50 may be based on any suitable programmable technology, such as fuses, antifuses, electrically programmable read-only-memory technology, random-access memory cells, mask-programmed elements, and so forth.

Many programmable logic devices are electrically programmed. With electrical programming arrangements, the programmable elements 50 may be formed from one or more memory cells. For example, during programming, configuration data is loaded into the memory cells using input/output pins 44 and input/output circuitry 42. In one embodiment, the memory cells may be implemented as random-access-memory (RAM) cells. The use of memory cells based on RAM technology as described herein is intended to be only one example. Further, since these RAM cells are loaded with configuration data during programming, they are sometimes referred to as configuration RAM cells (CRAM). These memory cells may each provide a corresponding static control output signal that controls the state of an associated logic component in programmable logic 48. For instance, in some embodiments, the output signals may be applied to the gates of metal-oxide-semiconductor (MOS) transistors within the programmable logic 48.

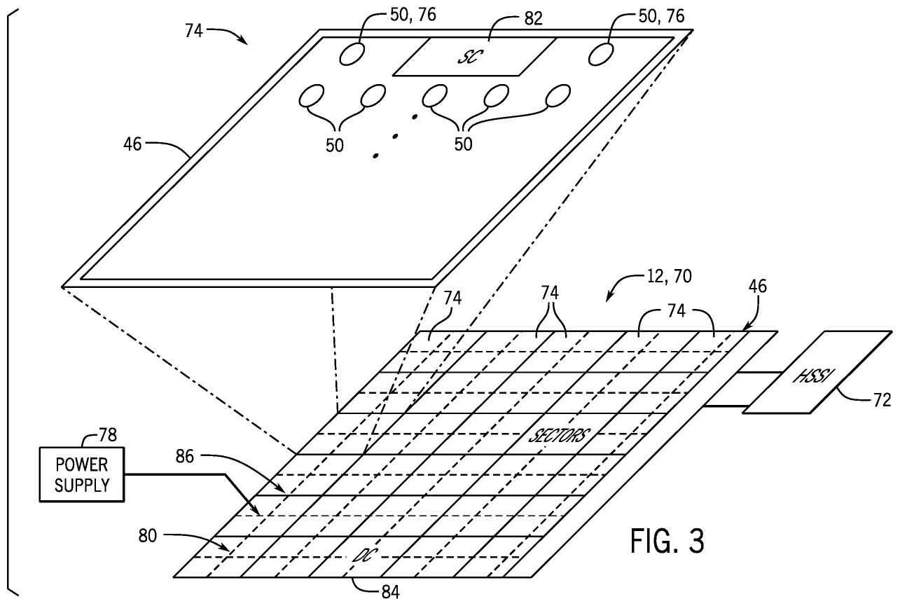

The integrated circuit device 12 may include any programmable logic device such as a field programmable gate array (FPGA) 70, as shown in FIG. 3. For the purposes of this example, the FPGA 70 is referred to as an FPGA, though it should be understood that the device may be any suitable type of programmable logic device (e.g., an application-specific integrated circuit and/r application-specific standard product). In one example, the FPGA 70 is a sectorized FPGA of the type described in U.S. Patent Publication No. 2016/0049941, “Programmable Circuit Having Multiple Sectors,” which is incorporated by reference in its entirety for all purposes. The FPGA 70 may be formed on a single plane. Additionally or alternatively, the FPGA 70 may be a three-dimensional FPGA having a base die and a fabric die of the type described in U.S. Pat. No. 10,833,679, “Multi-Purpose Interface for Configuration Data and User Fabric Data,” which is incorporated by reference in its entirety for all purposes.

In the example of FIG. 3, the FPGA 70 may include transceiver 72 that may include and/or use input/output circuitry, such as input/output circuitry 42 in FIG. 2, for driving signals off the FPGA 70 and for receiving signals from other devices. Interconnection resources 46 may be used to route signals, such as clock or data signals, through the FPGA 70. The FPGA 70 is sectorized, meaning that programmable logic resources may be distributed through a number of discrete programmable logic sectors 74. Programmable logic sectors 74 may include a number of programmable logic elements 50 having operations defined by configuration memory 76 (e.g., CRAM). A power supply 78 may provide a source of voltage (e.g., supply voltage) and current to a power distribution network (PDN) 80 that distributes electrical power to the various components of the FPGA 70. Operating the circuitry of the FPGA 70 causes power to be drawn from the power distribution network 80.

There may be any suitable number of programmable logic sectors 74 on the FPGA 70. Indeed, while 29 programmable logic sectors 74 are shown here, it should be appreciated that more or fewer may appear in an actual implementation (e.g., in some cases, on the order of 50, 100, 500, 1000, 5000, 10,000, 50,000 or 100,000 sectors or more). Programmable logic sectors 74 may include a sector controller (SC) 82 that controls operation of the programmable logic sector 74. Sector controllers 82 may be in communication with a device controller (DC) 84.

Sector controllers 82 may accept commands and data from the device controller 84 and may read data from and write data into its configuration memory 76 based on control signals from the device controller 84. In addition to these operations, the sector controller 82 may be augmented with numerous additional capabilities. For example, such capabilities may include locally sequencing reads and writes to implement error detection and correction on the configuration memory 76 and sequencing test control signals to effect various test modes.

The sector controllers 82 and the device controller 84 may be implemented as state machines and/or processors. For example, operations of the sector controllers 82 or the device controller 84 may be implemented as a separate routine in a memory containing a control program. This control program memory may be fixed in a read-only memory (ROM) or stored in a writable memory, such as random-access memory (RAM). The ROM may have a size larger than would be used to store only one copy of each routine. This may allow routines to have multiple variants depending on “modes” the local controller may be placed into. When the control program memory is implemented as RAM, the RAM may be written with new routines to implement new operations and functionality into the programmable logic sectors 74. This may provide usable extensibility in an efficient and easily understood way. This may be useful because new commands could bring about large amounts of local activity within the sector at the expense of only a small amount of communication between the device controller 84 and the sector controllers 82.

Sector controllers 82 thus may communicate with the device controller 84, which may coordinate the operations of the sector controllers 82 and convey commands initiated from outside the FPGA 70. To support this communication, the interconnection resources 46 may act as a network between the device controller 84 and sector controllers 82. The interconnection resources 46 may support a wide variety of signals between the device controller 84 and sector controllers 82. In one example, these signals may be transmitted as communication packets.

The use of configuration memory 76 based on RAM technology as described herein is intended to be only one example. Moreover, configuration memory 76 may be distributed (e.g., as RAM cells) throughout the various programmable logic sectors 74 of the FPGA 70. The configuration memory 76 may provide a corresponding static control output signal that controls the state of an associated programmable logic element 50 or programmable component of the interconnection resources 46. The output signals of the configuration memory 76 may be applied to the gates of metal-oxide-semiconductor (MOS) transistors that control the states of the programmable logic elements 50 or programmable components of the interconnection resources 46.

As discussed above, some embodiments of the programmable logic fabric may be configured using indirect configuration techniques. For example, an external host device may communicate configuration data packets to configuration management hardware of the FPGA 70. The data packets may be communicated internally using data paths and specific firmware, which are generally customized for communicating the configuration data packets and may be based on particular host device drivers (e.g., for compatibility). Customization may further be associated with specific device tape outs, often resulting in high costs for the specific tape outs and/or reduced salability of the FPGA 70.

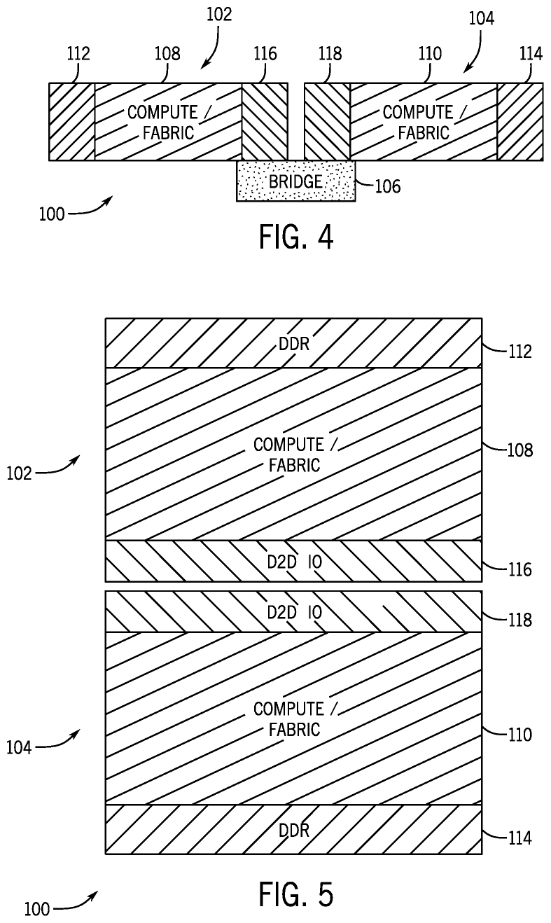

With the foregoing in mind, FIG. 4 is a block diagram of a side view of a package 100 that includes two die 102 and 104. The die 102 and 104 may include integrated circuits and be the integrated circuit device 10 of FIG. 1. Additionally or alternatively, the die 102 and/or 104 may include any other integrated circuit devices (e.g., memory, memory controllers, CPUs, etc.) that may be used in a multi-die/multi-chip/multi-chiplet package. The die 102 and 104 are communicatively coupled together via a bridge 106 or an interposer.

As illustrated, the die 102 and 104 each include a respective compute or fabric core (e.g., compute/fabric) 108 and 110 that perform the functions (e.g., compute, store, etc.) of the respective die 102 and 104. The die 102 and 104 further include respective IO circuitries 112 and 114, such as IO circuitry 42, which enable the die 102 and 104 to communicate with other devices (e.g., escape the package to off-package devices). Additionally, the die 102 and 104 may communicate with each other using die-to-die (D2D) circuitry 116 and 118 that enables the die 102 and 104 to interact through the bridge 106.

FIG. 5 is a block diagram of the package 100 showing a top-down view of the package 100 with the bridge 106 being under the die 102 and 104. The top-down view shows that the D2D circuitry 116 and 118 consume entire respective shoreline sides of the respective die 102 and 104. Some implementations of the die 102 and/or 104 may utilize a large number of IO interfaces, such as double-data rate (DDR) connections. However, the die 102 and/or 104 may not have enough available shoreline to implement such IO interfaces due to the shoreline consumed by the D2D circuitry 116 and/or 118 that limits the top silicon at the shoreline to be only used for D2D connections.

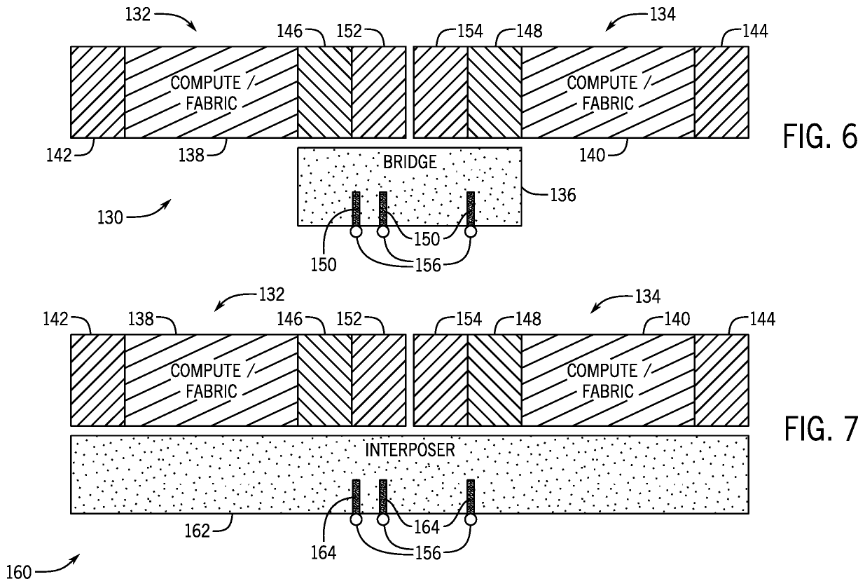

FIG. 6 is a block diagram of a side view of an embodiment of a package 130 that has an “extended” shoreline that provides more connectability as may be utilized by some interconnect (e.g., DDR) interfaces. Specifically, the package 130 includes die 132 and 134. The die 132 and 134 are interconnected using a bridge 136. Similar to the package 100, the die 132 and 134 may include integrated circuits and/or be the integrated circuit device 10 of FIG. 1. Additionally or alternatively, the die 132 and/or 134 may include any other integrated circuit devices (e.g., memory, memory controllers, CPUs, etc.) that may be used in a multi-die/multi-chip/multi-chiplet package. The die 132 and 134 are communicatively coupled together via a bridge 136 or an interposer.

As illustrated, the die 132 and 134 each include a respective compute or fabric core (e.g., compute/fabric) 138 and 140 that perform the functions (e.g., compute, store, etc.) of the respective die 132 and 134. The die 132 and 134 further include respective TO circuitries 142 and 144, such as TO circuitry 42, which enable the die 132 and 134 to communicate with other devices (e.g., escape the package to off-package devices). Additionally, the die 132 and 134 may communicate with each other using die-to-die (D2D) circuitry 146 and 148 that enables the die 132 and 134 to interact through the bridge 136. Furthermore, as illustrated, the bridge 136 includes through-silicon-vias (TSVs) 150 that provide an escape path for data from the die 132 and 134 off package. For instance, the package 130 may include bumps 156 to provide the connection between the first die 132 and the second die 134 to off-package electronic devices through the TSVs 150. The bumps 156 may include microbumps, C4 bumps, ball grid array (BGA) solder balls, or any other suitable bump type.

Using these escape paths as the TSVs 150, additional TO circuitry 152 and 154 may be utilized to communicate to and from the die 132 and/or 134 to an off-package electronic device even with the die 132 and 134 using the D2D circuitry 146 and 148 to communicate on the same respective sides of the die 132 and 134. Furthermore, although the package 130 includes a bridge with TSVs 150, other packages may utilize other interconnect types. For example, FIG. 7 shows a block diagram of a side view of a package 160 that is similar to the package 100 except that the package 160 includes an interposer 162 that has TSVs 164 instead of the bridge 136.

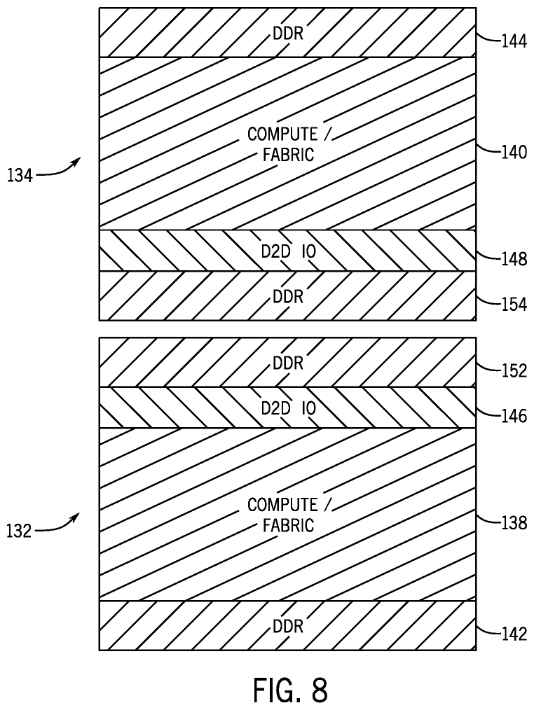

FIG. 8 is a block diagram of the package 130 or the package 160 showing a top-down view with the bridge 136 or interposer 162 being under the die 132 and 134. The top-down view shows that the D2D circuitry 146 and 148 consume entire respective shoreline sides of the respective die 132 and 134. Some implementations of the die 132 and/or 134 may utilize a large number of IO interfaces, such as double-data rate (DDR) or GPIO connections even when at least part of one shoreline is consumed by D2D circuitry. Indeed, the die 132 and/or 134 may have enough available “shoreline” to implement such IO interfaces (e.g., DDR) and D2D circuitry on the same respective edges between the die 132 and 134.

In some embodiments, the interposer 162 (or the bridge 136) may be used to accommodate data in addition or alternative to the IO escape. For instance, if the die 102 or the die 104 utilize a columnar IO with three-dimensions, the TSVs 150 or 164 may accommodate the IO escape and/or columnar IO chiplets (e.g., their connections on the same edge as D2D connections).

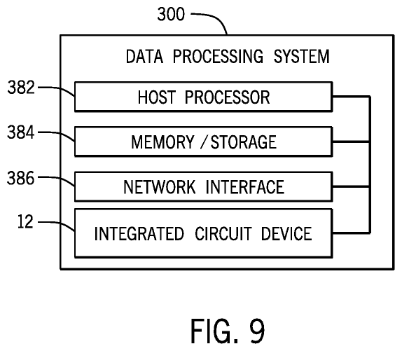

Furthermore, the integrated circuit device 12, the package 130, and/or the package 160 may generally be a data processing system or a component, such as an FPGA, included in a data processing system 300. For example, the integrated circuit device 12, the package 130, and/or the package 160 may be a component of a data processing system 300 shown in FIG. 9. The data processing system 300 may include a host processor 382 (e.g., a central-processing unit (CPU)), memory and/or storage circuitry 384, and a network interface 386. The data processing system 300 may include more or fewer components (e.g., electronic display, user interface structures, application specific integrated circuits (ASICs)). The host processor 382 may include any suitable processor, such as an INTEL® Xeon® processor or a reduced-instruction processor (e.g., a reduced instruction set computer (RISC), an Advanced RISC Machine (ARM) processor) that may manage a data processing request for the data processing system 300 (e.g., to perform debugging, data analysis, encryption, decryption, machine learning, video processing, voice recognition, image recognition, data compression, database search ranking, bioinformatics, network security pattern identification, spatial navigation, or the like). The memory and/or storage circuitry 384 may include random access memory (RAM), read-only memory (ROM), one or more hard drives, flash memory, or the like. The memory and/or storage circuitry 384 may hold data to be processed by the data processing system 300. In some cases, the memory and/or storage circuitry 384 may also store configuration programs (bitstreams) for programming the integrated circuit device 12, the package 130, and/or the package 160. The network interface 386 may allow the data processing system 300 to communicate with other electronic devices. The data processing system 300 may include several different packages or may be contained within a single package on a single package substrate.

In one example, the data processing system 300 may be part of a data center that processes a variety of different requests. For instance, the data processing system 300 may receive a data processing request via the network interface 386 to perform acceleration, debugging, error detection, data analysis, encryption, decryption, machine learning, video processing, voice recognition, image recognition, data compression, database search ranking, bioinformatics, network security pattern identification, spatial navigation, digital signal processing, or some other specialized tasks.

While the embodiments set forth in the present disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

### Example Embodiments

EXAMPLE EMBODIMENT 1. A system, comprising: a first die comprising a first side with first die-to-die circuitry and first input output circuitry; a second die comprising a second side with second die-to-die circuitry and second input output circuitry, wherein the first and second sides are adjacent to each other; and a semiconductor bridge comprising:

a plurality of connections to interconnect the first and second die-to-die circuitries; and

a plurality of through-silicon-vias to transmit data to or from the first and second input output circuitries through the semiconductor bridge.

EXAMPLE EMBODIMENT 2. The system of example embodiment 1, comprising an integrated circuit device package comprising the first die, the second die, and the semiconductor bridge.

EXAMPLE EMBODIMENT 3. The system of example embodiment 2, wherein the plurality of through-silicon-vias provide a connection from first die and the second die to electronic devices outside of the integrated circuit device package.

EXAMPLE EMBODIMENT 4. The system of example embodiment 1, wherein the plurality of through-silicon-vias comprises:

a first set of through-silicon-vias transporting first sets of data to and from the first die through the semiconductor bridge and not to or from the second die; and

a second set of through-silicon-vias transporting second sets of data to and from the second die and not to or from the first die.

EXAMPLE EMBODIMENT 5. The system of example embodiment 1, wherein the first input output circuitry is on an outermost edge on the first side.

EXAMPLE EMBODIMENT 6. The system of example embodiment 5, wherein the first die-to-die circuitry is between the first input output circuitry and a compute portion of the first die.

EXAMPLE EMBODIMENT 7. The system of example embodiment 1, wherein the second input output circuitry is on an outermost edge on the second side.

EXAMPLE EMBODIMENT 8. The system of example embodiment 7, wherein the second die-to-die circuitry is between the second input output circuitry and a compute portion of the second die.

EXAMPLE EMBODIMENT 9. A system, comprising: a first die comprising a first side with first die-to-die circuitry and first input output circuitry; a second die comprising a second side with second die-to-die circuitry and second input output circuitry, wherein the first and second sides are adjacent to each other; and an interposer comprising:

a plurality of connections to interconnect the first and second die-to-die circuitries; and

a plurality of through-silicon-vias to transmit data to or from the first and second input output circuitries through the interposer.

EXAMPLE EMBODIMENT 10. The system of example embodiment 9, comprising an integrated circuit device package comprising the first die, the second die, and the interposer.

EXAMPLE EMBODIMENT 11. The system of example embodiment 10, wherein the plurality of through-silicon-vias provide a connection from the first die and the second die to electronic devices outside of the integrated circuit device package.

EXAMPLE EMBODIMENT 12. The system of example embodiment 9, wherein the plurality of through-silicon-vias comprises a first set of through-silicon-vias transporting first sets of data to and from the first die through the interposer and not to or from the second die; and a second set of through-silicon-vias transporting second sets of data to and from the second die and not to or from the first die.

EXAMPLE EMBODIMENT 13. The system of example embodiment 9, wherein the first input output circuitry is on an outermost edge on the first side.

EXAMPLE EMBODIMENT 14. The system of example embodiment 13, wherein the first die-to-die circuitry is between the first input output circuitry and a compute portion of the first die.

EXAMPLE EMBODIMENT 15. The system of example embodiment 9, wherein the second input output circuitry is on an outermost edge on the second side.

EXAMPLE EMBODIMENT 16. The system of example embodiment 15, wherein the second die-to-die circuitry is between the second input output circuitry and a compute portion of the second die.

EXAMPLE EMBODIMENT 17. An electronic package device, comprising: a first die comprising a first side with first die-to-die circuitry and first input output circuitry; a second die comprising a second side with second die-to-die circuitry and second input output circuitry, wherein the first and second sides are adjacent to each other in the electronic package device; and a semiconductor interconnect comprising:

a plurality of connections to interconnect the first and second die-to-die circuitries; and

a plurality of through-silicon-vias to transmit data to or from the first and second input output circuitries through the semiconductor interconnect.

EXAMPLE EMBODIMENT 18. The electronic package device of example embodiment 17, wherein the semiconductor interconnect comprises a silicon bridge.

EXAMPLE EMBODIMENT 19. The electronic package device of example embodiment 17, wherein the semiconductor interconnect comprises an interposer.

EXAMPLE EMBODIMENT 20. The electronic package device of example embodiment 17, wherein the first input output circuitry is on a first outermost edge on the first side, the first die-to-die circuitry is between the first input output circuitry and a compute portion of the first die, the second input output circuitry is on an outermost edge on the second side, and the second die-to-die circuitry is between the second input output circuitry and a compute portion of the second die.

What is claimed is:

1. A system, comprising:
a first die comprising a first side with first die-to-die circuitry and first input output circuitry;
a second die comprising a second side with second die-to-die circuitry and second input output circuitry, wherein the first and second sides are adjacent to each other; and
a semiconductor bridge comprising:
a plurality of connections to interconnect the first and second die-to-die circuitries; and
a plurality of through-silicon-vias to transmit data to or from the first and second input output circuitries through the semiconductor bridge.

2. The system of claim 1, comprising an integrated circuit device package comprising the first die, the second die, and the semiconductor bridge.

3. The system of claim 2, wherein the plurality of through-silicon-vias to at least partially provide a connection from first die and the second die to electronic devices outside of the integrated circuit device package.

4. The system of claim 3, comprising a plurality of bumps coupled to a side of the bridge away from the first and second die, wherein the plurality of bumps are to at least partially provide the connection from the first die and the second die to the electronic devices outside of the integrated circuit device package.

5. The system of claim 1, wherein the plurality of through-silicon-vias comprises:
a first set of through-silicon-vias transporting first sets of data to and from the first die through the semiconductor bridge and not to or from the second die; and
a second set of through-silicon-vias transporting second sets of data to and from the second die and not to or from the first die.

6. The system of claim 1, wherein the first input output circuitry is on an outermost edge on the first side.

7. The system of claim 6, wherein the first die-to-die circuitry is between the first input output circuitry and a compute portion of the first die.

8. The system of claim 1, wherein the second input output circuitry is on an outermost edge on the second side.

9. The system of claim 7, wherein the second die-to-die circuitry is between the second input output circuitry and a compute portion of the second die.

10. A system, comprising:
a first die comprising a first side with first die-to-die circuitry and first input output circuitry;
a second die comprising a second side with second die-to-die circuitry and second input output circuitry, wherein the first and second sides are adjacent to each other; and
an interposer comprising:
a plurality of connections to interconnect the first and second die-to-die circuitries; and
a plurality of through-silicon-vias to transmit data to or from the first and second input output circuitries through the interposer.

11. The system of claim 10, comprising an integrated circuit device package comprising the first die, the second die, and the interposer.

12. The system of claim 11, wherein the plurality of through-silicon-vias provide a connection from the first die and the second die to electronic devices outside of the integrated circuit device package.

13. The system of claim 10, wherein the plurality of through-silicon-vias comprises:
a first set of through-silicon-vias transporting first sets of data to and from the first die through the interposer and not to or from the second die; and
a second set of through-silicon-vias transporting second sets of data to and from the second die and not to or from the first die.

14. The system of claim 10, wherein the first input output circuitry is on an outermost edge on the first side.

15. The system of claim 14, wherein the first die-to-die circuitry is between the first input output circuitry and a compute portion of the first die.

16. The system of claim 10, wherein the second input output circuitry is on an outermost edge on the second side, and the second die-to-die circuitry is between the second input output circuitry and a compute portion of the second die.

17. An electronic package device, comprising:
a first die comprising a first side with first die-to-die circuitry and first input output circuitry;
a second die comprising a second side with second die-to-die circuitry and second input output circuitry, wherein the first and second sides are adjacent to each other in the electronic package device; and
an interconnect comprising:
a plurality of connections to interconnect the first and second die-to-die circuitries; and
a plurality of through-silicon-vias to transmit data to or from the first and second input output circuitries through the interconnect.

18. The electronic package device of claim 17, wherein the interconnect comprises a silicon bridge, an interposer, or a combination thereof.

19. The electronic package device of claim 17, wherein the interconnect comprises an active interposer, an active bridge, or a combination thereof.

20. The electronic package device of claim 17, wherein the first input output circuitry is on a first outermost edge on the first side, the first die-to-die circuitry is between the first input output circuitry and a compute portion of the first die, the second input output circuitry is on an outermost edge on the second side, and the second die-to-die circuitry is between the second input output circuitry and a compute portion of the second die.
